(19) United States
(12) Patent Application Publication
(10) Pub. No.: US 2007/0107875 A1
(43) Pub. Date: May 17, 2007

(54) Flat plate heat transfer device

(76) Inventors: Young-Duck Lee, Euiwang-si (KR); Min-Jung Oh, Anyang-si (KR); Hyun-Tae Kim, Seoul (KR); Sung-Wook Jang, Seoul (KR)

Correspondence Address: JONES DAY, 222 EAST 41ST ST, NEW YORK, NY, 10017, US

(21) Appl. No.: 10/580,995

(22) PCT Filed: Nov. 24, 2004
(86) PCT No.: PCT/KR04/03042

§ 371 Date: May 26, 2006

(30) Foreign Application Priority Data
Nov. 27, 2003 (KR) 10-2003-0085182
Apr. 1, 2004 (KR) 10-2004-0022676

(51) Int. Cl. H05K 7/20

(52) U.S. Cl. 165/104.26; 165/104.33; 361/700

(57) ABSTRACT

Disclosed is a flat plate heat transfer device, which includes a thermally conductive flat case installed between a heat source and a heat emitting unit and containing a working fluid evaporated with absorbing heat from the heat source and condensed with emitting heat to the heat emitting unit; and a mesh layer aggregate installed in the flat case and having a structure that a fine mesh layer for providing a flowing path of liquid and a coarse mesh layer for providing a flowing path of liquid and a dispersion path of vapor simultaneously are laminated. On occasions, the coarse and the fine mesh layers are alternately laminated repeatedly, and the fine mesh layer is replaced with a wick structure. The coarse mesh layer is preferably a screen mesh layer with wire diameter of 0.2 mm˜0.4 mm and mesh number of 10˜20. This device improves heat transfer performance.

### TECHNICAL FIELD

The present invention relates to a flat plate heat transfer device capable of emitting heat from a heat source by circulating a working fluid using evaporation and condensation, and more particularly to a flat plate heat transfer device capable of having thinner structure as well as excellent heat transferring and dissipating structure.

### BACKGROUND ART

In recent, an electronic equipment such as notebook or PDA becomes smaller and thinner along with the development of integration technique. In addition, together with the increased demands for high response of an electronic equipment and improvement of functions, energy consumption is also tending increased. Accordingly, much heat is generated from electronic parts in the electronic equipment while the equipment is operated, so various flat plate heat transfer devices are used to emit the heat outside.

A traditional example of the conventional flat plate heat transfer device is a heat pipe in which a flat metal case is decompressed to a vacuum and then a working fluid is injected and sealed therein.

The heat pipe is installed so that it is partially in contact with an electronic component generating heat (or, a heat source). In this case, a working fluid near the heat source is heated and evaporated, and is then dispersed to a region with a relatively lower temperature. And then, the vapor is condensed into liquid again with emitting heat outside, and then returns to its initial position. By means of such working fluid circulating mechanism conducted in the flat metal case, the heat generated in the heat source is emitted outside, and the temperature of the electronic component may be kept in a suitable level accordingly.

FIG. 1 shows that a conventional flat plate heat transfer device 10 is installed between a heat source 20 and a heatsink 30 to transfer heat from the heat source 20 to the heatsink 30.

Referring to FIG. 1, the conventional flat plate heat transfer device 10 has a metal case 50 whose inner space 40 is filled by a working fluid. On an inner side of the metal case 50, a wick structure 60 is formed for providing an efficient working fluid circulating mechanism.

The heat generated in the heat source 20 is transferred to the wick structure 60 in the flat plate heat transfer device 10, contacted with the heat source 20. Then, the working fluid contained at the wick structure 60 (that is acting as ‘an evaporating part’) approximately right above the heat source 20 is evaporated and dispersed in all directions through the inner space 40, and the working fluid is then condensed again after emitting heat at the wick structure 60 (that is acting as ‘a condensing part’) approximately right below the heatsink 30. The condensed working fluid is received in the wick structure 60, and then returns to the evaporating part again by means of capillary force. At this time, if the heat source 20 has higher temperature than the evaporation point of the working fluid, the evaporation, dispersion, condensation and return processes are repeated. The heat emitted in the condensation step is transferred to the heatsink 30, and then discharged out by means of the forced convection by a fan 70.

In order to improve heat transfer performance of the flat plate heat transfer device 10, a larger amount of working fluid should be circulated per unit time. For this purpose, a large surface area should be ensured for evaporation and condensation of the working fluid, and there should be provided a vapor channel for the evaporated working fluid to be effectively dispersed and a liquid channel for the condensed working fluid to be flowed near to the heat source 20 as fast as possible.

However, in the conventional flat plate heat transfer device 10, the surface on which a working fluid may be evaporated or condensed is limited to an inner surface of the metal case 50 that is faced with the heat source 20 or the heatsink 30, so there is a limit in obtaining a large surface area for evaporation or condensation of a working fluid.

In addition, in the conventional flat plate heat transfer device 10, the condensed working fluid is received in uneven portions of the wick structure 60 provided on the inner surface of the metal case 50, and is flowed to the evaporating part by means of capillary force. That is to say, the channel through which the condensed working fluid may flow is limitedly formed only along the inner surface of the metal case 50.

Accordingly, a distance that the condensed working fluid should flow through the liquid channel is several times of a distance that the evaporated working fluid flows through the vapor channel. As a result, a time taken for the condensed working fluid to be returned is much longer than a time taken for the evaporated working fluid to be dispersed. If there exists a significant difference between the time taken for return of the condensed working fluid and the time taken for dispersion of the evaporated working fluid, a flow rate of working fluid that may be circulated per unit time is decreased, and thus the heat transfer performance of the flat plate heat transfer device is also deteriorated.

Furthermore, since the inside of the flat plate heat transfer device 10 is substantially decompressed to a vacuum, it is somewhat weak against an external impact. Thus, if an impact is applied thereto while the flat plate heat transfer device 10 is being manufactured or carried, the metal case 50 is apt to be crushed.

### DISCLOSURE OF INVENTION

The present invention is designed to solve the problems of the prior art, and therefore it is an object of the present invention to provide a flat plate heat transfer device with a structure that is capable of decreasing a distance for a condensed working fluid to flow so as to maximize heat transfer performance of the flat plate heat transfer device, causing flow of liquid and vapor at the same time, and increasing a mechanical strength of the device with keeping its heat transfer mechanism as it is.

Another object of the invention is to provide a flat plate heat transfer device with a geometric structure that allows a larger amount of working fluid to be evaporated or condensed, thereby maximizing heat transfer performance.

In order to accomplish the above object, the present invention provides a flat plate heat transfer device, which includes a thermally conductive flat case installed between a heat source and a heat emitting unit, and containing a working fluid that is evaporated with absorbing heat from the heat source and condensed with emitting heat to the heat emitting unit; and a mesh layer aggregate installed in the flat case and having a structure that wick structure for providing a flowing path of liquid by means of capillary force and coarse mesh layer for providing a flowing path of liquid by means of capillary force and a dispersion path of vapor at the same time are laminated with being opposite to each other, wherein the coarse mesh layer is a screen mesh with a wire diameter from 0.20 mm to 0.40 mm and a mesh number from 10 to 20.

Preferably, the coarse mesh layer provides a flowing path of liquid in horizontal and vertical directions by means of capillary force at the same time. In addition, the coarse mesh layer is preferably made of metal material in order to improve heat transfer performance.

Selectively, the mesh layer aggregate may further include another wick structure which is opposite to the wick structure with the coarse mesh wire interposed therebetween and which is contacted with the coarse mesh layer.

In the present invention, the wick structure may be made by sintered copper, stainless steel, aluminum or nickel powder, or by etching polymer, silicon, silica (SiO₂), copper, stainless steel, nickel or aluminum plate.

As an alternative, the wick structure may be replaced with a fine mesh layer that has a relatively larger mesh number and a smaller wire diameter than the coarse mesh layer. In this case, the fine mesh layer may be a screen mesh woven by mesh wires with a diameter from 0.03 mm to 0.13 mm or having a mesh number from 80 to 400.

In another aspect of the invention, there is also provided a flat plate heat transfer device, which includes a thermally conductive flat case installed between a heat source and a heat emitting unit, and containing a working fluid that is evaporated with absorbing heat from the heat source and condensed with emitting heat to the heat emitting unit; and a mesh layer aggregate installed in the flat case and having a structure that fine mesh layers and coarse mesh layers are alternately laminated repeatedly.

The fine mesh layers and the coarse mesh layers are preferably alternately laminated to be contacted with each other. In addition, the coarse mesh layer and the fine mesh layer are preferably woven by mesh wires made of metal, polymer, plastic or glass fiber.

As an example, the mesh layer aggregate may have a structure that is laminated in the order of fine mesh layer, coarse mesh layer, fine mesh layer, coarse mesh layer and fine mesh layer, from bottom to top.

As another example, the mesh layer aggregate may also have a structure that is laminated in the order of fine mesh layer, coarse mesh layer, fine mesh layer and coarse mesh layer, from bottom to top.

As still another example, the mesh layer aggregate may also have a structure that is laminated in the order of at least two fine mesh layers, coarse mesh layer, fine mesh layer and coarse mesh layer, from bottom to top.

As still another example, the mesh layer aggregate may also have a structure that is laminated in the order of at least two fine mash layers, coarse mesh layer, fine mesh layer, coarse mesh layer and at least two fine mesh layers, from bottom to top.

In still another aspect of the invention, there is also provided a flat late heat transfer device, which includes a thermally conductive flat case installed between a heat source and a heat emitting unit and containing a working fluid that is evaporated with absorbing heat from the heat source and condensed with emitting heat to the heat emitting unit; and a mesh layer aggregate installed in the flat case and having a structure that a wick structure for providing a flowing path of liquid by means of capillary force and a coarse mesh layer for providing a flowing path of liquid by means of capillary force and a dispersion path of vapor at the same time are alternately laminated repeatedly with being contacted with each other.

In the present invention, the flat case may be made of any of metal, conductive polymer, metal coated with conductive polymer, and conductive plastic, or electrolytic copper foil. In the latter case, a uneven surface of the electrolytic copper foil preferably configures an inner surface of the flat case. The flat case may be sealed using a manner selected from the group consisting of laser welding, plasma welding, TIG (Tungsten Inert Gas) welding, ultrasonic welding, brazing, soldering, and thermo-compression lamination.

In the present invention, the working fluid may be water, methanol, ethanol, acetone, ammonia, CFC working fluid, HCFC working fluid, HFC working fluid, or their mixtures.

### BRIEF DESCRIPTION OF THE DRAWINGS

Other objects and aspects of the present invention will become apparent from the following description of embodiments with reference to the accompanying drawing in which:

FIG. 1 is a sectional view showing a conventional flat plate heat transfer device;

FIG. 2 is a sectional view showing a flat plate heat transfer device according to a first embodiment of the present invention;

FIG. 3 is a plane view showing a lattice of a mesh layer that composes a mesh layer aggregate according to the first embodiment of the present invention;

FIG. 4 is a sectional view taken along an A-A′ line of FIG. 3;

FIG. 5 shows that liquid membranes existing in a fine mesh layer and a coarse mesh layer adjacent to each other are interconnected in the mesh layer aggregate according to the first embodiment of the present invention;

FIG. 6 shows that liquid membranes formed at crossing points of mesh wires are interconnected in the coarse mesh layer according to the first embodiment of the present invention;

FIG. 7 is a sectional view showing a flat plate heat transfer device according to a second embodiment of the present invention;

FIGS. 8 to 10 are sectional views showing various modifications of the mesh layer aggregate according to the present invention;

FIGS. 11 to 13 are perspective views showing various appearances of the flat plate heat transfer device according to the present invention; and

FIGS. 14 to 16 are sectional views showing various examples of a flat case used in the flat plate heat transfer device according to the present invention.

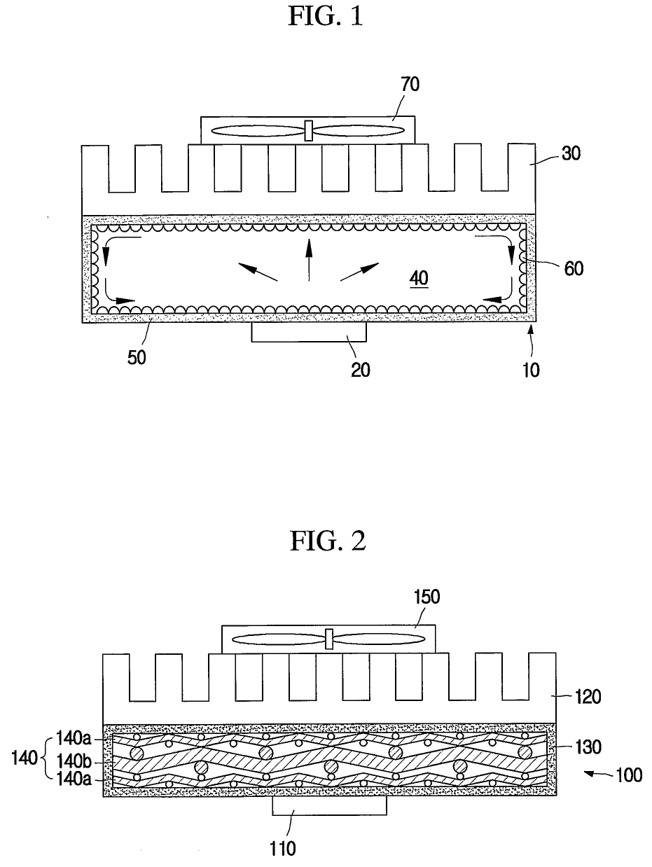

### BEST MODES FOR CARRYING OUT THE INVENTION

Hereinafter, embodiments are described for specifying the present invention, and detailed description will be provided with reference to the accompanying drawings for better understanding of the invention. However, the embodiments of the present invention may be modified in various ways, and it should not be interpreted that the scope of the invention is limited to the embodiments described below. The embodiments of the invention are provided just for clearer and more definite illustration to those having ordinary skill in the art. In the drawings, the same reference numeral designates the same element.

A flat plate heat transfer device 100 according to a first embodiment of the present invention includes a flat case 130 installed between a heat source 110 and a heat emitting unit 120 such as a heatsink, and a mesh layer aggregate 140 composed of a plurality of mesh layers inserted into the flat case 130, as shown in FIG. 2. In the flat case 130, a working fluid that is evaporated with absorbing heat generated in the heat source 110 and condensed with emitting heat to the heat emitting unit 120 is injected.

The mesh layer aggregate 140 includes a fine mesh layer 140a, a coarse mesh layer 140b, and a fine mesh layer 140a. The fine mesh layers 140a are opposite to each other with forming a contact interface with the coarse mesh layer 140b.

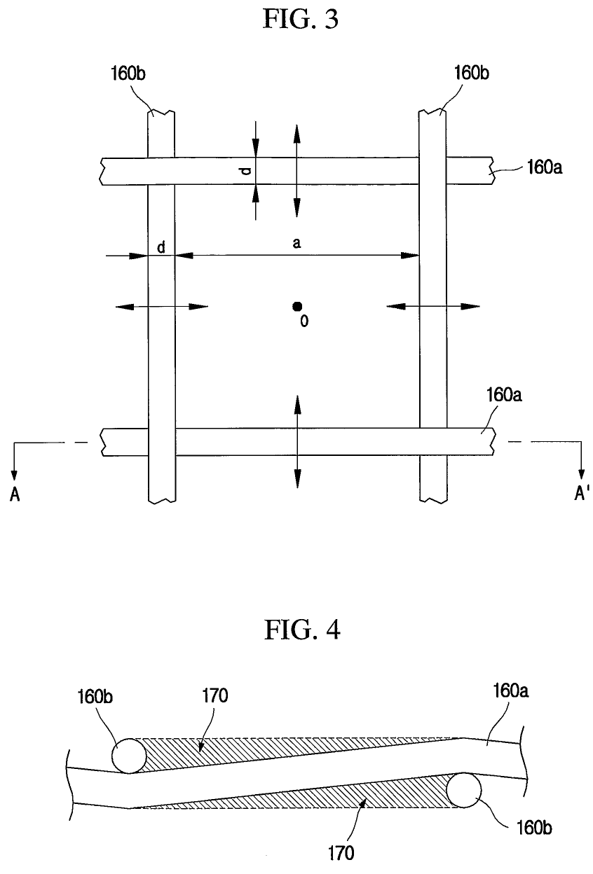

The fine mesh layer 140a and the coarse mesh layer 140b are preferably screen meshes in which widthwise wires 160a and lengthwise wires 160b are woven to be alternately crossed up and down, as shown in FIG. 3. Here, the lengthwise wire 160b is a mesh wire arranged in row in a length direction of the mesh layer when being woven, while the widthwise wire 160a is a mesh wire arranged perpendicular to the lengthwise wire 160b.

The mesh wires 160a and 160b are made of any of metal, polymer, glass fiber and plastic. However, since metal has more excellent heat transfer performance than other materials, the mesh layers 140a and 140b are preferably woven by metal wires in view of heat transfer efficiency. Preferably, the metal is any of copper, aluminum, stainless steel and molybdenum, or their alloy.

Referring to FIG. 3, a width (a) of an empty space existing in a unit lattice of the mesh layers 140a and 140b is generally expressed like the following equation 1. The width (a) becomes an essential parameter to determine a functional feature of the mesh layers 140a and 140b.
a=(1−Nd)/N Equation 1

Here, d is a diameter (inch) of the mesh wire, and N is the number of lattices existing in a length of 1 inch. For example, if N is 100, 100 mesh lattices exist in a length of 1 inch.

If the device 100 does not conduct heat transfer operation since a temperature of the heat source 110 is lower than an evaporating temperature of the working fluid, there exist physically absorbed working fluids on the surface and at crossing points of wires that compose the mesh layers 140a and 140b. In case of the coarse mesh layer 140b, the empty space of the mesh lattice is not entirely filled with liquid membrane of the working fluid. However, in case of the fine mesh layer 140a, the entire empty space of the lattice is filled with liquid membrane of the working fluid.

In case that the temperature of the heat source 110 is higher than the evaporating temperature of the working fluid, the flat plate heat transfer device 100 initiates heat transfer operation from the heat source 110 to the heat emitting unit 120. Specifically, the heat generated in the heat source 110 is transferred to the adjacent fine mesh layer 140a, thereby causing evaporation of the working fluid in the fine mesh layer 140a. Of course, evaporation of the working fluid is also induced in the coarse mesh layer 140b, but an amount of evaporated working fluid in the coarse mesh layer 140b is smaller than that in the fine mesh layer 140a. The working fluid evaporated as mentioned above is then dispersed through adjacent coarse mesh layers 140b, and it is then condensed in an area having a lower temperature than the evaporating temperature of the working fluid on the inner surface of the flat case 130, namely in a fine mesh layer 140a positioned substantially right below the heat emitting unit 120.

While evaporation and condensation of the working fluid are repeated, the working fluid takes heat from the heat source 110 and then transfers the heat to the heat emitting unit 120. The heat transferred to the heat emitting unit 120 is then discharged outward by means of forced convection by a fan 150, so the temperature of the heat source 110 is kept within a suitable level. In an ideal case, the working fluid heat transfer mechanism using evaporation and condensation of the working fluid is continued until the temperature of the heat source 110 becomes substantially equal to the temperature of the heat emitting unit 120.

If evaporation and condensation of the working fluid is induced in the flat plate heat transfer device 100, an equilibrium state of interface energy is disturbed in the mesh layer aggregate 140. Here, the interface energy means energy of a contact interface between the working fluid in a liquid state and the surface of the mesh layers 140a and 140b. That is to say, the interface energy is increased at a point where evaporation of the working fluid is induced rather than the case before the heat transfer occurs (in an equilibrium state), while the interface energy is reduced at a point where condensation of the working fluid is induced rather than the case before the heat transfer occurs (in an equilibrium state). As a result, a tendency to solve disturbance of the interface energy is generated in the mesh layer aggregate 140.

Accordingly, a tendency to introduce the working fluid from surroundings is generated at the point where the working fluid is evaporated, and a tendency to discharge the working fluid to surroundings is generated at the point where the working fluid is condensed. This makes a flow of the condensed working fluid in the mesh layer aggregate 140. On the average, the flow of the condensed working fluid is generated from the heat emitting unit 120 to outer surroundings of the mesh layer aggregate 140, and again from the outer surroundings toward the heat source 110.

In the flat plate heat transfer device 100, the coarse mesh layer 100b provides a dispersion path of the evaporated working fluid mainly as mentioned above. Specifically, a wedge-shaped space generated by up and down crossing of the widthwise wires 160a and the lengthwise wires 160b as shown in FIG. 4 exists in the coarse mesh layer 140b, and this space acts as a vapor dispersion channel 170 through which vapor may be dispersed.

A geometric area (A) of the vapor dispersion channel 170 is calculated like the following equation 2.
A=(a+d)d−πd²/4 Equation 2

Seeing the equation 2, the geometric area of the vapor dispersion channel 170 is increased as the mesh number (N) is decreased and the diameter (d) of the mesh wire is increased.

Since the lattice of the coarse mesh layer 140b has four vapor dispersion channels 170 possessed in common with adjacent lattices in total, dispersion of the vapor is conducted in four directions (see arrows ‘ [symbol] ’ in FIG. 3) on the basis of the center (see ‘0’ of FIG. 3) of the mesh lattice.

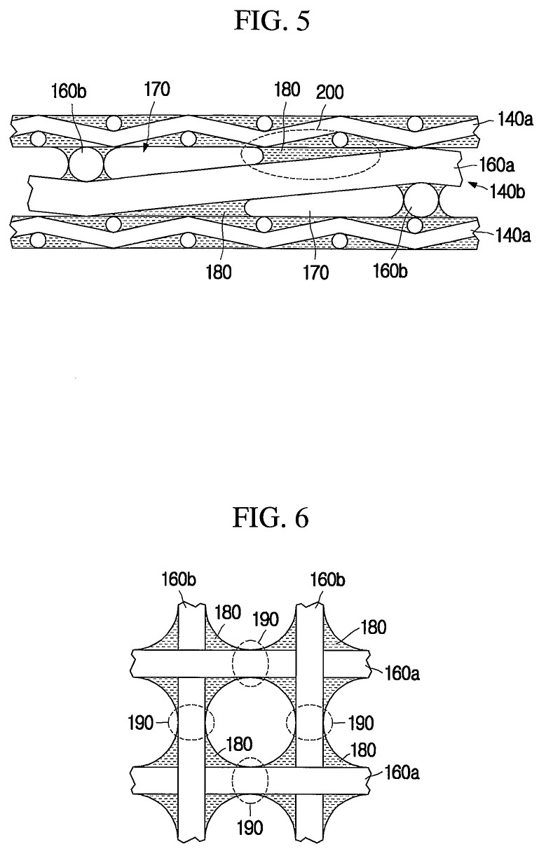

Meanwhile, when the flat plate heat transfer device 100 of the present invention is actually operated, a liquid membrane 180 is formed by the working fluid in a liquid state at the wedge-shaped gap of the vapor dispersion channel 170 on the coarse mesh layer 140b, as shown in FIG. 5. The liquid membrane 180 is formed at all crossing points of the coarse mesh wires 160 as shown in FIG. 6, and liquid membranes formed adjacent to each other are interconnected (see reference numeral 190 in FIG. 6).

Connection of the liquid membranes 180 is enabled when a width (N) of mesh lattice and/or a diameter (d) of mesh wire is suitably controlled among parameters of the coarse mesh layer 140b, and it plays a role of causing horizontal flow of the working fluid by means of capillary force. Thus, at the coarse mesh layer 140b, dispersion of vapor is mainly induced through the vapor dispersion channel 170, but horizontal flow of liquid is also induced by means of capillary force caused to the connected liquid membranes 180. A rate of the horizontal flow induced at this time is relatively lower than that induced at the fine mesh layer 140a.

The liquid membranes 180 are connected not only in the coarse mesh layer 140b but also to liquid membranes existing at the fine mesh layers 140a right above and right below the coarse mesh layer 140b (see reference numeral 200 in FIG. 5). Connection between liquid membranes in different mesh layers is obtained through a contact interface formed between the coarse mesh layer 140b and the fine mesh layer 140a. In the operation of the flat plate heat transfer device 100, the interconnection between a liquid membrane existing at the coarse mesh layer 140b and a liquid membrane existing at the fine mesh layer 140a ensures vertical flow of the liquid between different layers.

As described above, at a region of the fine mesh layer 140a right above the heat source 110, evaporation of liquid is continuously induced during the heat transfer procedure, so liquid should be supplied thereto continuously correspondingly. However, in order that liquid is continuously supplied to the fine mesh layer 140a, in view of a geometric structure of the mesh layer aggregate 140, the coarse mesh layer 140b arranged between the fine mesh layers 140a should make a cross-linking role for the vertical flow of the condensed working fluid. Such vertical flow of the working fluid is enabled by means of vertical connection (see reference numeral 200 in FIG. 5) of the liquid membranes 180 existing at the fine mesh layer 140a and the coarse mesh layer 140b. That is to say, the vertical connection of the liquid membranes 180 keeps the capillary force in a vertical direction so that the condensed working fluid may flow smoothly even in a vertical direction.

Since the coarse mesh layer 140b provides the vapor dispersion channel 170 as mentioned above, the coarse mesh layer 140b allows the working fluid evaporated at the fine mesh layer 140a to be rapidly dispersed to a region with a lower temperature than the heat source 110, and at the same time the coarse mesh layer 140b plays a cross-linking role for vertical flow of the working fluid so that the condensed working fluid may be smoothly supplied to an adjacent fine mesh layer 140a. Accordingly, the condensed working fluid is smoothly supplied near to the heat source 110 while the flat plate heat transfer device 100 is operating, thereby maximizing heat transfer efficiency of the device 100. In addition, the coarse mesh layer 140b also plays a role of supporting the flat case 130 to enhance mechanical strength of the flat plate heat transfer device 100, thereby allowing the device 100 to be extremely thinner.

At the coarse mesh layer 140b, dispersion of vapor and flow of liquid should be generated at the same time, so suitable selection is required for the number of meshes and a diameter of mesh wire. At this time, it should be noted that, if the mesh number of the coarse mesh layer 140b is very large and the diameter of mesh wire is very small, an area of the vapor dispersion channel 170 is decreased to make flow resistance of vapor increased and the vapor dispersion channel 170 itself is filled with liquid by means of surface tension to make dispersion of vapor be not induced.

Considering the fact, in case of using a screen mesh conforming to ASTM specification E-11-95 as the coarse mesh layer 140b, the screen mesh preferably has a mesh number from 10 to 20 and a diameter of mesh wire from 0.2 mm to 0.4 mm. If the screen mesh having such conditions is selected, dispersion of vapor and horizontal and vertical flow of liquid are induced at the same time in the coarse mesh layer 140b.

During the operation procedure of the flat plate heat transfer device 100, evaporation of the liquid is induced at the fine mesh layer 140a near the heat source 110 and condensation of the vapor is induced at the fine mesh layer 140a near the heat emitting unit 120. In this process, the liquid should be continuously smoothly supplied from a portion below the heat emitting unit 120 to a portion above the heat source 110 on the average by means of the capillary force induced in a horizontal or vertical direction.

For this purpose, it is preferable that the interconnected liquid membranes 180 providing capillary force exist at the wire crossing points of the fine mesh layer 140a, and empty spaces of the lattice are filled with the liquid membranes. This may be obtained by suitably selecting a mesh number and a wire diameter of the fine mesh layer 140a.

In case of using a screen mesh conforming to ASTM specification E-11-95 as the fine mesh layer 140a, it is preferable that a screen mesh with a mesh number from 80 to 400 and a diameter of mesh wire from 0.03 mm to 0.13 mm is selected.

In the first embodiment of the present invention described above, the fine mesh layer 140a may be replaced with a wick structure. In some cases, the fine mesh layer 140a below the heat emitting unit 120 may be excluded when. In this case, since the liquid membrane is formed at the coarse mesh layer 140b and the working fluid is condensed at this portion as shown in FIGS. 5 and 6, the coarse mesh layer itself plays a role of a condensation part of the working fluid. The wick structure may be made by sintered copper, stainless steel, aluminum or nickel powder, or made by etching polymer, silicon, silica, copper, stainless steel, nickel or aluminum plate. Furthermore, the wick structure may be made using the micro-machining method disclosed in U.S. Pat. No. 6,056,044 issued to Benson, et al.

In the present invention, the flat case 130 containing the mesh layer aggregate 140 is decompressed to a vacuum, and its material is selected from metal with excellent thermal conductivity, conductive polymer, metal coated with conductive polymer or thermally conductive plastic so that it may easily absorb heat from the heat source 110 and emit the heat to the heat emitting unit 120 again.

Preferably, the metal is any of copper, aluminum, stainless steel and molybdenum, or their alloy. In particular, in case that the flat case 130 is made of an electrolytic copper foil with unevenness as small as about 10 μm on one side surface, the uneven surface preferably composes an inner surface of the flat case 130. In this case, flow of the working fluid is also induced on the inner surface of the flat case 130 by means of capillary force, so the working fluid may return near to the heat source 110 more rapidly, thereby increasing heat transfer performance of the flat plate heat transfer device 100 further. The flat case 130 preferably has a thickness from 0.01 mm to 3.0 mm in consideration of its heat transfer characteristic and mechanical strength.

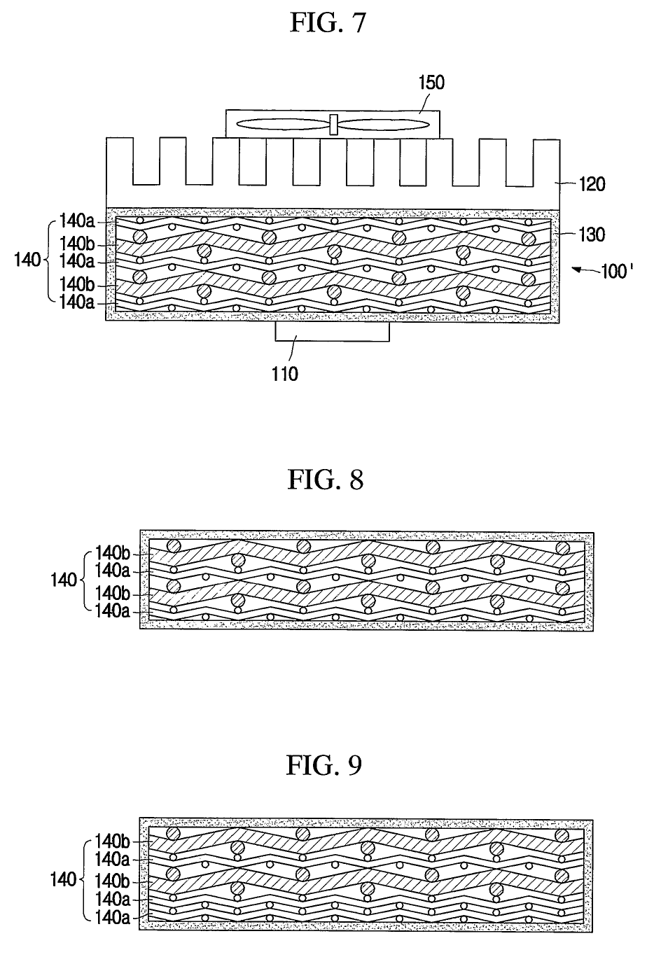

FIG. 7 shows a flat plate heat transfer device according to a second embodiment of the present invention. The device of the second embodiment is substantially identical to that of the first embodiment, except a laminating manner of the mesh layer aggregate.

Referring to FIG. 7, the flat plate heat transfer device 100′ according to the second embodiment of the present invention includes a mesh layer aggregate 140 in which fine mesh layers 140a and coarse mesh layers 140b are alternately laminated. Here, the fine mesh layer 140a and the coarse mesh layer 140b are identical to those of the first embodiment, and contacted with each other in a lamination direction.

Such configuration of the mesh layer aggregate 140 ensures relatively more excellent heat transfer performance than that of the flat plate heat transfer device 100 shown in FIG. 2. Such excellent heat transfer performance may be realized since evaporation of the working fluid is induced in many places of a plurality of fine mesh layers 140a at the same time, then rapid dispersion of the vapor through a plurality of coarse mesh layers 140b is induced in many places at the same time, and the coarse mesh layers 140b play a role of a vapor dispersion channel and a cross-linking role for vertical flow of the condensed liquid, thereby reducing a returning time of the working fluid and increasing a flow rate of the working fluid per unit time supplied near to the heat source 110.

In the mesh layer aggregate 140, a unit of alternately laminated mesh layer is not limited to one. However, if more than three fine mesh layers 140a are composed, the evaporated working fluid may be collected in the laminated structure of the fine mesh layers 140a to hinder flow of the liquid. Thus, the number of laminated fine mesh layers 140a is preferably two or less.

During the operation procedure of the flat plate heat transfer device 100′, the heat generated in the heat source 110 is transferred not only to an adjacent fine mesh layer 140a but also to a fine mesh layer 140a not adjacent thereto, so evaporation of the working fluid is induced in many places at the same time in each fine mesh layer 140a. Accordingly, heat transfer performance per unit time is improved. Evaporation of the working fluid is also induced in the coarse mesh layer 140b, an amount of which is however much less than an amount of evaporated working fluid induced in the fine mesh layer 140a.

The evaporated working fluid is dispersed through a plurality of the coarse mesh layers 140b adjacent to the fine mesh layer 140a, and is then condensed at a region with a lower temperature than the evaporation point of the working fluid on the inner surface of the flat case 130, namely a region approximately right below the heat emitting unit 120. And then, the heat generated during condensation of the working fluid is emitted outward through the heat emitting unit 120.

The condensed working fluid is flowed near to the heat source 110 on the average by means of the capillary force induced in the mesh layer aggregate 140. At this time, flow of the condensed working fluid is mainly induced between the fine mesh layer 140a and the coarse mesh layer 140b that compose different layers, though it is also induced in the fine mesh layer 140a itself and the coarse mesh layer 140b itself. The flow of working fluid between the mesh layers composing different layers is realized through a contact interface between the mesh layers. At this time, the mechanism related to vertical flow of the working fluid is substantially identical to that of the former embodiment.

In particular, the coarse mesh layer 140b provides a vapor dispersion channel to give a function so that the working fluid evaporated at the fine mesh layer 140a may be rapidly dispersed to a region with a lower temperature than the heat source 110, and to give a cross-linking function for vertical flow of the working fluid so that the condensed working fluid may be supplied to the adjacent fine mesh layer 140a. Accordingly, during the operation procedure of the flat plate heat transfer device 100′, the condensed working fluid is rapidly supplied near to the heat source 110, thereby maximizing heat transfer efficiency of the device 100′.

In the second embodiment of the present invention, the method for composing the mesh layer aggregate 140 with fine mesh layer 140a and coarse mesh layer 140b may be variously modified from the example shown in FIG. 7. FIGS. 8 to 10 show such various modifications.

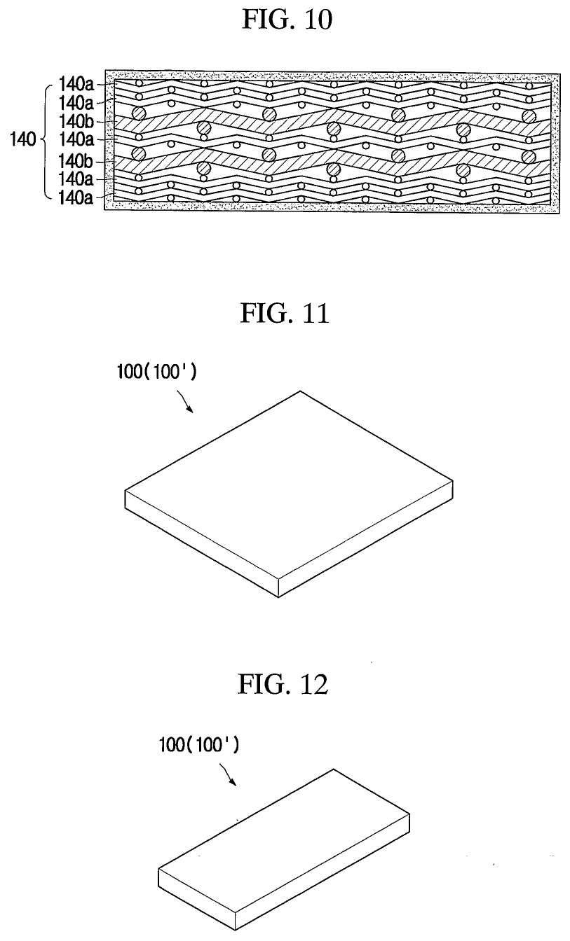

Referring to FIGS. 8 to 10 in comparison to FIG. 7, as an example, a fine mesh layer 140a at the top layer may be excluded in composing the mesh layer aggregate 140 (see FIG. 8). As another example, the top layer and the bottom layer may be configured with a plurality fine mesh layers 140a (see FIG. 10). As still another example, a fine mesh layer 140a at the top layer may be excluded and the bottom layer may be configured with a plurality of fine mesh layers 140a (see FIG. 9).

Meanwhile, in the second embodiment and its modification of the present invention, the fine mesh layer that composes the mesh layer aggregate may be replaced with various kinds of wick structures well known in the art, similar to the first embodiment.

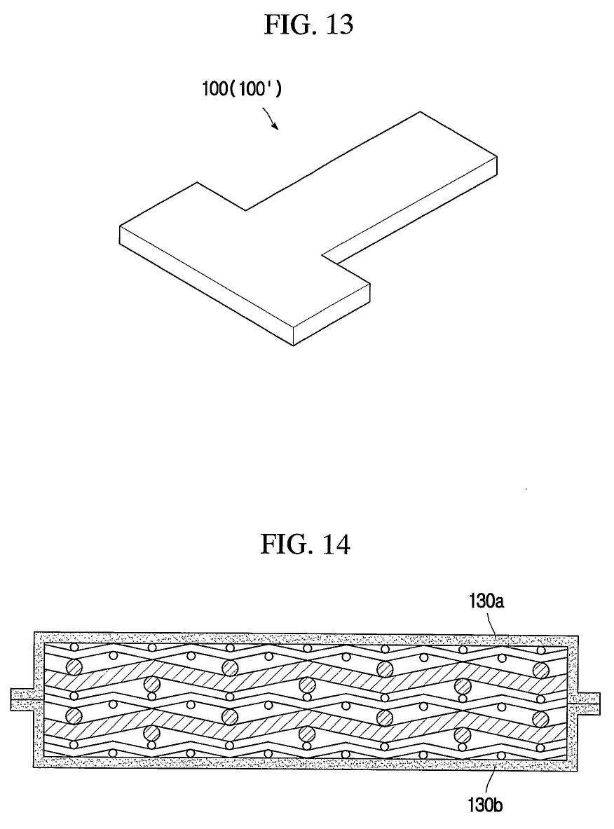

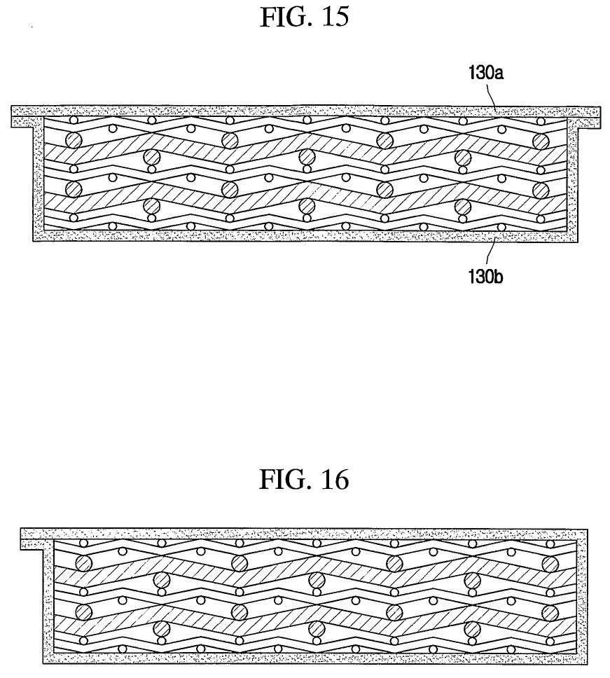

The flat plate heat transfer device according to the present invention may have various shapes such as square, rectangle, T-shape or the like as shown in FIGS. 11 to 13. In addition, the flat case of the flat plate heat transfer device may be configured with an upper case 130a and a lower case 130b that are provided separately as shown in FIGS. 14 and 15, or as an integrated one case as shown in FIG. 16.

In the present invention, the final sealing process of the flat case is conducted after a working fluid is filled therein with its inner space being decompressed to a vacuum. The sealing is conducted using a manner such as laser welding, plasma welding, TIG (Tungsten Inert Gas) welding, ultrasonic welding, brazing, soldering, and thermo-compression lamination.

The working fluid injected into the flat case may adopt water, methanol, ethanol, acetone, ammonia, CFC working fluid, HCFC working fluid, HFC working fluid, or their mixtures.

In the flat plate heat transfer device configured as mentioned above according to the present invention, the coarse mesh layer plays a role of a vapor dispersion channel as well as a cross-linking role for horizontal and vertical flow of the liquid. Such duplicated roles of the coarse mesh layer is essential to the flat plate heat transfer device of the present invention, and they may be achieved by suitably selecting a mesh number and a diameter of mesh wire of the coarse mesh layer.

Hereinafter, performance dependency of the heat transfer device according to a mesh number and a wire diameter of the coarse mesh layer adopted in the present invention is actually measured so as to calculate a condition with which the coarse mesh layer may perform duplicated actions by means of the following experiment 1.

Experiment 1

A screen mesh made of copper was selected for the coarse mesh layer in each case of the following Table 1. In addition, a screen mesh made of copper and having a mesh number of 100 and a mesh wire diameter of 0.11 mm was selected for the fine mesh layer. After that, 11 mesh layer aggregates were configured with a structure as shown in FIG. 2.

TABLE 1

| Case | Wire diameter [mm] | Mesh number [#/inch] | R [° C./W] |
|---|---|---|---|
| 1 | 0.20 | 15 | 0.70 |
| 2 | 0.20 | 24 | 0.74 |
| 3 | 0.20 | 50 | ∞ |
| 4 | 0.35 | 10 | 0.67 |
| 5 | 0.35 | 12 | 0.63 |
| 6 | 0.35 | 14 | 0.61 |
| 7 | 0.35 | 16 | 0.65 |
| 8 | 0.35 | 18 | 0.67 |
| 9 | 0.35 | 30 | ∞ |
| 10 | 0.48 | 10 | 0.78 |
| 11 | 0.71 | 8 | ∞ |

Subsequently, the plurality of mesh layer aggregates were mounted between upper and lower flat cases (see FIG. 14), and the flat cases were sealed by means of denatured acrylic binary bond (HARDLOC^{TH}, made by DENKA in Japan) with leaving a working fluid injection hole. At this time, an oxide free copper plate with a thickness of 0.2 mm was used for the flat case, and the flat case was 80 mm in length and 70 mm in width.

After the flat case was sealed as mentioned above, eleven samples of the flat plate heat transfer device were prepared by decompressing the inside of the flat case to 1.0×10⁻⁷ torr with the use of a rotary vacuum pump and a diffusion vacuum pump, filling 0.23 cc of distilled water therein as a working fluid, and then finally sealing the flat case.

After each flat plate heat transfer device was made, heat transfer performance of each device was measured as mentioned below, and its results are shown in the thermal resistance column of the table 1.

First, a copper block heat source having a length of 30 mm and a width of 30 mm was attached to an upper portion of the heat transfer device. Two cartridge-type heaters for giving heat (50 W, 240V) were installed in the copper block. A thermocouple was attached to the surface of the copper block so as to measure temperature of the copper surface. A fin heatsink made of copper was attached to a lower portion of the heat transfer device so that it may act as a heat emitting unit.

By using such configuration, the working fluid returns to its original position in a direction opposite to gravity, and a returning ability of the working fluid may be comparatively evaluated for each heat transfer device. The fin heatsink has the same length and width as the heat transfer device.

In the specific example, 90 W of heat capacity was supplied through the cartridge-type heaters in total. After that, a surface temperature of the copper block was measured at an ambient temperature 22° C. After that, a thermal resistance (R [° C./W] was calculated on the basis of the difference between the surface temperature of the copper block and the ambient temperature.

A thermal resistance of each heat transfer device is shown in the table 1. As a result of the experiment, the thermal resistance was lowest when a wire diameter is 0.35 mm and a mesh number is 14. When the wire has a diameter of 0.35 mm, the thermal resistance was increased as the mesh number was increased more than or decreased less than 14.

When a wire diameter is 0.35 mm, if a mesh number is decreased less than 14, an area of vapor channel is geometrically increased. However, the increase of the thermal resistance is caused by the fact that a pure area of the vapor channel is substantially not increased since an area occupied by the wedge-shaped liquid membrane formed on the section of the coarse mesh layer is increased together, but heat transfer ability of the coarse mesh layer is decreased due to the decrease of the mesh number. From the fact, it may be understood that the material of the coarse mesh layer gives an influence on the performance of the heat transfer device. Accordingly, when configuring the heat transfer device, the coarse mesh layer is preferably made of metal.

In addition, when a wire diameter is 0.35 mm, if a mesh number is increased more than 14, the thermal resistance is increased due to the fact that an increased amount of the thermal resistance according to the increase of the flow resistance caused by the reduction of the vapor channel is rather larger than an increased amount of heat transfer ability by means of thermal conductivity of the coarse mesh layer.

In particular, if a wire diameter is 0.2 mm and a mesh number is 50, the temperature of the copper surface is continuously increased, thereby not giving a result. It is because the vapor channel is too reduced and thus vapor is not dispersed to all parts of the flat plate heat transfer device, so the vapor is not condensed.

Through these experimental results, the inventors might analogize performance of the flat plate heat transfer device according to the change of a mesh number and a wire diameter of the coarse mesh layer, and also found that the flat plate heat transfer device may give an effective function as an actual cooling device if the coarse mesh layer has a wire diameter of 0.2 to 0.4 mm and a mesh number from 10 to 20.

Now, the inventors checked correlation of the heat transfer performance of the device according to the structure of the mesh layer aggregate by comparing heat transfer performance of the flat plate heat transfer device according to the first embodiment with that of the second embodiment.

Experiment 2

The inventors made a flat plate heat transfer device (hereinafter, referred to as a sample 1) with a length of 150 mm, a width of 50 mm and a height of 2.25 mm in order to check an effect of the flat plate heat transfer device according to the present invention. The flat case is configured by combining upper and lower flat cases that are separately prepared, and it is made of copper foil with a thickness of 0.1 mm.

A mesh layer aggregate to be mounted in the flat case is laminated as shown in FIG. 7 with the use of copper screen meshes in which a content of copper is at least 99%. A coarse mesh layer uses a screen mesh made of copper and in which a wire diameter is 0.35 mm, a layer thickness is 0.74 mm and a mesh number is 14. In addition, a fine mesh layer uses a screen mesh made of copper and in which a wire diameter is 0.11 mm, a layer thickness is 0.24 mm and a mesh number is 100.

In order to make the sample 1 to be used in this experiment, the mesh layer aggregate was at first mounted between the upper and lower cases, and the flat cases were sealed by means of denatured acrylic binary bond (HARDLOC^{TH}, made by DENKA in Japan) with leaving a working fluid injection hole.

After that, the inside of the flat case was decompressed to 1.0×10⁻⁷ torr with the use of a rotary vacuum pump and a diffusion vacuum pump, 3.91 cc of distilled water was filled therein as a working fluid, and then the flat cases were finally sealed.

Meanwhile, in order to compare performance of the flat plate heat transfer device made as mentioned above, a flat plate heat transfer device (hereinafter, referred to as a sample 2) in which a coarse mesh layer and a fine mesh layer were simply laminated was made. The coarse mesh layer and the fine mesh layer used to make the sample 2 were identical to them of the sample 1. The sample 2 was made in the same way as the sample 1, except that its thickness is 1.35 mm and a filled amount of working fluid is 3.12 cc.

After preparing the samples 1 and 2 as mentioned above, a fin heatsink with a length of 80 mm and a width of 61 mm on its lower surface and with a height of 40 mm was mounted on the above surface of each of the samples 1 and 2, and then a cooling fan was mounted thereon. In addition, a copper block heat source that is 31 mm in length and width respectively was attached to a lower surface of each of the samples 1 and 2. After that, a surface temperature of the heat source was measured under the same ambient condition and at a constant fan speed, with a thermal capacity of the heat source being 70 W.

As a result of the experiment, it was found that the heat source shows a temperature of 69° C. in case of the sample 2 and 58° C. in case of the sample 1 when an ambient temperature is 25° C. It shows that the performance of the flat plate heat transfer device is improved when fine mesh layers and coarse mesh layers are alternately laminated.

Through the experiments as above, it is understood that, if coarse mesh layers and fine mesh layers are alternately laminated like the flat plate heat transfer device according to the second embodiment, dispersion of the evaporated working fluid is conducted at many places simultaneously in a plurality of the coarse mesh layers, and the coarse mesh layers induce rapid return of the condensed working fluid through themselves, thereby improving the heat transfer performance.

### INDUSTRIAL APPLICABILITY

According to one aspect of the invention, lamination of coarse mesh layers and fine mesh layers (or, a wick structure) in the flat case causes vertical flow of the working fluid by means of capillary force, so the condensed working fluid may be rapidly and smoothly supplied near to the heat source.

According to another aspect of the invention, it is possible to induce evaporation and dispersion of working fluid at many places simultaneously in the mesh layer aggregate. In particular, since a large surface area for evaporation and condensation of the working fluid may be ensured in the screen meshes alternately laminated, the heat transfer performance of the flat plate heat transfer device is maximized.

According to still another aspect of the invention, since the mesh layer aggregate supports the flat case, it is possible to prevent the device from being deformed though a mechanical impact is applied thereto.

The present invention has been described in detail. However, it should be understood that the detailed description and specific examples, while indicating preferred embodiments of the invention, are given by way of illustration only, since various changes and modifications within the spirit and scope of the invention will become apparent to those skilled in the art from this detailed description.

1. A flat plate heat transfer device, comprising:
a thermally conductive flat case installed between a heat source and a heat emitting unit, and containing a working fluid that is evaporated with absorbing heat from the heat source and condensed with emitting heat to the heat emitting unit; and
a mesh layer aggregate installed in the flat case and having a structure that fine mesh layer and coarse mesh layer are laminated with being opposite to each other,
wherein the coarse mesh layer is a screen mesh with a wire diameter from 0.20 mm to 0.40 mm and a mesh number from 10 to 20.

2. The flat plate heat transfer device according to claim 1, further comprising another fine mesh layer which is opposite to the fine mesh layer with the coarse mesh layer interposed therebetween and which is contacted with the coarse mesh layer.

3. The flat plate heat transfer device according to claim 1 or 2,
wherein the fine mesh layer is a screen mesh woven by mesh wires with a diameter from 0.03 mm to 0.13 mm or having a mesh number from 80 to 400.

4. The flat plate heat transfer device according to claim 1 or 2,
wherein the coarse mesh layer is made of metal material.

5. A flat plate heat transfer device, comprising:
a thermally conductive flat case installed between a heat source and a heat emitting unit, and containing a working fluid that is evaporated with absorbing heat from the heat source and condensed with emitting heat to the heat emitting unit; and
a mesh layer aggregate installed in the flat case and having a structure that fine mesh layer and coarse mesh layer are laminated with being opposite to each other,
wherein the coarse mesh wire is a screen mesh made of metal material and having a wire diameter from 0.20 mm to 0.40 mm and a mesh number from 10 to 20, and provides a flowing path of liquid in horizontal and vertical directions by means of capillary force and a dispersion path of vapor.

6. A flat plate heat transfer device, comprising:
a thermally conductive flat case installed between a heat source and a heat emitting unit, and containing a working fluid that is evaporated with absorbing heat from the heat source an condensed with emitting heat to the heat emitting unit; and
a mesh layer aggregate installed in the flat case and having a structure that wick structure and coarse mesh layer are laminated with being opposite to each other,
wherein the coarse mesh layer is a screen mesh with a wire diameter from 0.20 mm to 0.40 mm and a mesh number from 10 to 20.

7. The flat plate heat transfer device according to claim 6, further comprising another wick structure which is opposite to the wick structure with the coarse mesh wire interposed therebetween and which is contacted with the coarse mesh layer.

8. The flat plate heat transfer device according to claim 6 or 7,
wherein the wick structure is made by sintering copper, stainless steel, aluminum, or nickel powder.

9. The flat plate heat transfer device according to claim 6 or 7,
wherein the wick structure is made by etching polymer, silicon, silica (SiO₂), copper, stainless steel, nickel or aluminum plate.

10. The flat plate heat transfer device according to claim 6 or 7,
wherein the coarse mesh layer is made of metal material.

11. A flat plate heat transfer device, comprising:
a thermally conductive flat case installed between a heat source and a heat emitting unit, and containing a working fluid that is evaporated with absorbing heat from the heat source and condensed with emitting heat to the heat emitting unit; and
a mesh layer aggregate installed in the flat case and having a structure that wick structure and coarse mesh layer are laminated with being opposite to each other,
wherein the coarse mesh wire is a screen mesh made of metal material with a wire diameter from 0.20 mm to 0.40 mm and a mesh number from 10 to 20, and provides a flowing path of liquid in horizontal and vertical directions by means of capillary force and a dispersion path of vapor.

12. A flat plate heat transfer device, comprising:
a thermally conductive flat case installed between a heat source and a heat emitting unit, and containing a working fluid that is evaporated with absorbing heat from the heat source and condensed with emitting heat to the heat emitting unit; and
a mesh layer aggregate installed in the flat case and having a structure that fine mesh layers and coarse mesh layers are alternately laminated repeatedly.

13. The flat plate heat transfer device according to claim 12,
wherein the coarse mesh layer is a screen mesh woven by mesh wires with a diameter from 0.2 to 0.4 mm and having a mesh number from 10 to 20.

14. The flat plate heat transfer device according to claim 12,
wherein the fine mesh layer is a screen mesh woven by mesh wires with a diameter from 0.03 to 0.13 mm or having a mesh number from 80 to 400.

15. The flat plate heat transfer device according to claim 12,
wherein the fine mesh layers and the coarse mesh layers are alternately laminated to be contacted with each other.

16. The flat plate heat transfer device according to claim 12,
wherein the mesh layer aggregate has a structure that is laminated in the order of fine mesh layer, coarse mesh layer, fine mesh layer, coarse mesh layer and fine mesh layer, from bottom to top.

17. The flat plate heat transfer device according to claim 12,
wherein the mesh layer aggregate has a structure that is laminated in the order of fine mesh layer, coarse mesh layer, fine mesh layer and coarse mesh layer, from bottom to top.

18. The flat plate heat transfer device according to claim 12,
wherein the mesh layer aggregate has a structure that is laminated in the order of at least two fine mesh layers, coarse mesh layer, fine mesh layer and coarse mesh layer, from bottom to top.

19. The flat plate heat transfer device according to claim 12,
wherein the mesh layer aggregate has a structure that is laminated in the order of at least two fine mesh layers, coarse mesh layer, fine mesh layer, coarse mesh layer and at least two fine mesh layers, from bottom to top.

20. The flat plate heat transfer device according to claim 12,
wherein the fine mesh layer provides a flowing path of liquid.

21. The flat plate transfer device according to claim 12,
wherein the coarse mesh layer provides a flowing path of liquid and a dispersion path of vapor at the same time.

22. The flat plate heat transfer device according to claim 1.
wherein the flat case is made of electrolytic copper foil, and
wherein a uneven surface of the electrolytic copper foil configures an inner surface of the flat case.

23. The flat plate heat transfer device according to claim 12,
wherein the coarse mesh layers and the fine mesh layers are woven by mesh wires made of metal, polymer, plastic or glass fiber.

24. The flat plate heat transfer device according to any of claim 1,
wherein the flat case is made of metal, conductive polymer, metal coated with conductive polymer, or conductive plastic.

25. The flat plate heat transfer device according to claim 24,
wherein the metal is copper, aluminum, stainless steel, molybdenum, or their alloys.

26. The flat plate heat transfer device according to claim 1, wherein the flat case is sealed using a manner selected from the group consisting of laser welding, plasma welding, TIG (Tungsten Inert Gas) welding, ultrasonic welding, brazing, soldering, and thermo-compression lamination.

27. The flat plate heat transfer device according to claim 1,
wherein the working fluid is selected from the group consisting of water, methanol, ethanol, acetone, ammonia, CFC working fluid, HCFC working fluid, HFC working fluid, and their mixtures.

28. A flat plate heat transfer device, comprising:
a thermally conductive flat case installed between a heat source and a heat emitting unit and containing a working fluid that is evaporated with absorbing heat from the heat source and condensed with emitting heat to the heat emitting unit; and
a mesh layer aggregate installed in the flat case and having a structure that a wick structure for providing a flowing path of liquid by means of capillary force and a coarse mesh layer for providing a flowing path of liquid by means of capillary force and a dispersion path of vapor at the same time are alternately laminated repeatedly with being contacted with each other.

29. The flat plate heat transfer device according to claim 28,
wherein the wick structure is made by sintering copper, stainless steel, aluminum or nickel powder.

30. The flat plate heat transfer device according to claim 28,
wherein the wick structure is made by etching polymer, silicon, silica (SiO₂), copper, stainless steel, nickel or aluminum plate.

31. The flat plate heat transfer device according to claim 28,
wherein the wick structure or the coarse mesh layer is no less than 2-layer structure.
